(19) United States
(12) Patent Application Publication
(10) Pub. No.: US 2026/0161102 A1
(43) Pub. Date: Jun. 11, 2026

(54) DEVICE ALIGNMENT FOR CORRECTING SUBSTRATE ANGLE

(71) Applicant: Onto Innovation Inc., Wilmington, MA (US)

(72) Inventor: Stephen W. Into, Hudson, NH (US)

(21) Appl. No.: 19/410,065

(22) Filed: Dec. 5, 2025

Related U.S. Application Data
(60) Provisional application No. 63/730,341, filed on Dec. 10, 2024.

(51) Int. Cl. G03F 9/00; G01B 11/27; G03F 7/00; G06T 7/00; H10P 72/50

(52) U.S. Cl. CPC G03F 9/7011; G01B 11/272; G03F 7/7075; G03F 9/7015; G03F 9/7049; G03F 9/7092; G06T 7/001; H10P 72/53

(57) ABSTRACT

The present application discloses an apparatus and a method for performing device alignment on a substrate. The apparatus comprises at least one camera mounted opposite the substrate to capture at least one image of at least a portion of a plurality of constructed devices on the substrate; and a device aligner to align substrate based on the at least portion of the constructed devices, wherein the device aligner is configured to detect a pattern of the at least portion of the plurality of constructed devices from the at least one image, generate an alignment offset correction based on the detected pattern, and align the substrate based on the alignment offset correction.

### CROSS-REFERENCE TO RELATED APPLICATION

This application claims the benefit of priority to U.S. Provisional Patent Application Ser. No. 63/730,341 filed Dec. 10, 2024, the contents of which are incorporated herein by reference in its entirety.

### TECHNICAL FIELD

The present disclosure is directed to techniques for performing device alignment on a substrate, more particularly, performing substrate alignment utilizing image-based pattern detection to determine and correct angular misalignment.

### BACKGROUND

Inspection and metrology applications in semiconductor manufacturing position substrates to ensure proper imaging and measurement. In some conventional systems, substrate pre-alignment can be based on the shape of the outside of the substrate or of the substrate's edge features. This approach relies implicitly on the assumption that the device patterns formed on the substrate are well-aligned to the outer geometry of the substrate. In real applications, however, a perfect alignment between the device patterns and the substrate edges or fiducial features typically does not exist. Therefore, these conventional approaches may lead to misalignment between the patterns and the image axes of the equipment. Such misalignment can severely degrade the accuracy of the inspection or measurement and also the performance of the system in general.

### SUMMARY

Some conventional approaches for performing alignment utilize mechanical edge detection or pre-defined fiducials for placement of the substrate with respect to the process equipment. These methods neglect changes caused during lithography, etching, or other material handling processes which may result in rotational or translational offsets between the substrate edges and the actual orientation of the device pattern. Equipment such as an inspection microscope or metrology tool, therefore, images the substrate at less-than-optimal angles. This can result in a blurred, distorted, or incomplete pattern data from the device. Thereby not only decreasing the accuracy of inspection but also increasing the need for manual adjustment or re-measurement.

Accordingly, the present disclosure describes techniques for performing substrate alignment prior to inspection that utilize image-based pattern detection to determine and correct angular misalignment.

One aspect of the present disclosure provides an apparatus for performing device alignment on a substrate. The apparatus comprising: at least one camera mounted opposite the substrate to capture at least one image of at least a portion of a plurality of constructed devices on the substrate; and a device aligner to align substrate based on the at least portion of the constructed devices, wherein the device aligner is configured to detect a pattern of the at least portion of the plurality of constructed devices from the at least one image, generate an alignment offset correction based on the detected pattern, and align the substrate based on the alignment offset correction.

Another aspect of the present disclosure provides a method for device alignment on a substrate. The method comprising: receiving a substrate comprising a plurality of constructed devices; capturing at least one image of the substrate, the image comprising at least a portion of the plurality of constructed devices; detecting a pattern of the at least portion of the plurality of constructed devices based on the at least one image; generating an alignment offset correction based on the detected pattern; and aligning the substrate based on the alignment offset correction.

Yet another aspect of the present disclosure provides a pre-alignment system. The system comprising: at least one camera mounted opposite a substrate to capture at least one image of at least a portion of a plurality of constructed devices on the substrate; and means for aligning the substrate based on the at least portion of the plurality of constructed devices on the substrate.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Additional aspects, features, and/or advantages of examples will be set forth in part in the description which follows and, in part, will be apparent from the description, or may be learned by practice of the disclosure.

### BRIEF DESCRIPTION OF THE DRAWINGS

Various ones of the appended drawings merely illustrate example implementations of the present disclosure and should not be considered as limiting its scope.

FIG. 1A shows alignment errors relative to outside boundary of substrate, according to an example of the present disclosure.

FIG. 1B shows alignment errors based on constructed devices, according to an example of the present disclosure.

FIG. 2 illustrates a schematic diagram of a substrate handling and alignment system, according to an example of the present disclosure.

FIG. 3 illustrates a block diagram of an apparatus for performing device alignment, according to an example of the present disclosure.

FIG. 4 illustrates a flow diagram of a method for device alignment on a substrate, according to an example of the present disclosure.

FIG. 5 illustrates a flow diagram of a method for generating alignment offset correction using cross-correlation, according to an example of the present disclosure.

FIG. 6 illustrates a flow diagram of a method for performing pre-alignment and device alignment, according to an example of the present disclosure.

FIG. 7 illustrates a block diagram of an example comprising a machine upon which any one or more of the techniques (e.g., methodologies) discussed herein may be performed.

### DETAILED DESCRIPTION

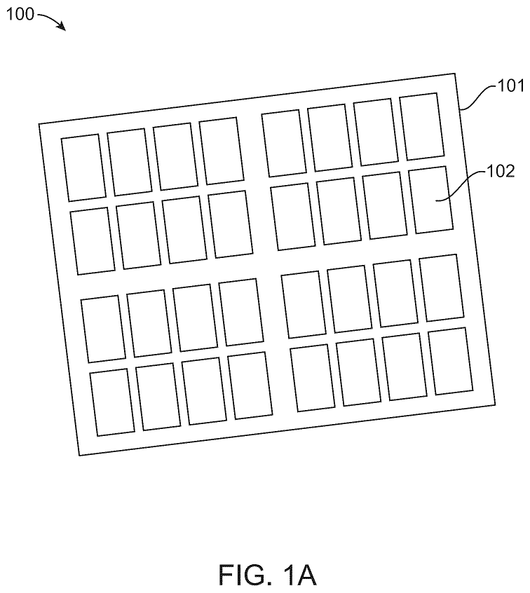

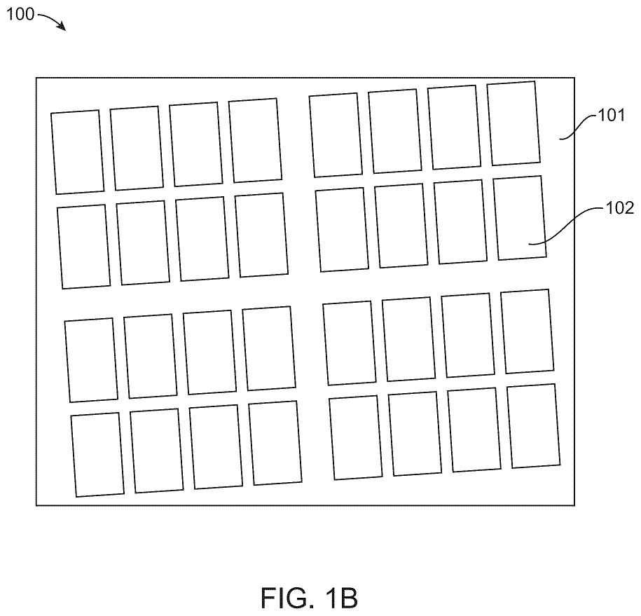

Some conventional pre-aligners can adjust the orientation of the substrate primarily based on the outer shape, position of notches or marks, or other peripheral features of the substrate. This pre-alignment functions well only when the constructed devices or patterns on the substrate are well-aligned to the outside shape or peripheral features of the substrate as shown in FIG. 1A. In this case, the constructed devices 102 on the substrate 101 are aligned with the outer boundary of the substrate 101. However, in some scenarios, as shown in FIG. 1B, where the plurality of constructed devices 102 are misaligned relative to the outer boundary of the substrate 102, positioning the substrate solely based on the outer shape of the substrate would result in rotational offsets between the constructed devices 102 and the optical axes of the equipment, affecting the functional efficiency of the equipment.

The device alignment techniques described herein address this and other issues. The device alignment techniques, for example, may detect the orientation of the constructed devices 102 relative to the optical axes of the equipment and correct them accordingly.

A substrate can be any flat material that is used in semiconductor or related manufacturing. For example, the substrate can be a panel or a wafer. A wafer can be of various types including elemental semiconductors (e.g., silicon or germanium), compound semiconductors (e.g., gallium arsenide (GaAs) or gallium nitride (GaN)), or variety of other substrate types known in the art (including conductive, semiconductive, and non-conductive substrates, such as glass).

In some embodiments, the substrate can be a panel. The panel may serve as a base upon one or more layers of material are applied and processed to create a multilayered substrate. A panel is generally a flat object made of semiconductor materials, glass, or composite materials. Panels typically have a rectangular or square shape and come in a variety of sizes. In some embodiments, the panel can be in the form of a copper core laminate (CCL) panel, a glass panel substrate, or other panel constructed of soda-lime glass treated with one or more special coatings to improve the adhesion and uniformity of deposited materials.

The substrate includes a plurality of microfabricated features, referred to herein as constructed devices. The constructed devices may include a plurality of redistribution layers (RDLs), with closely spaced RDL lines (conductive traces), pads, vias, interconnects or other circuity or transistors.

Embodiments of the present disclosure relates to an apparatus and method for correcting substrate angle relative to an optical axes of a processing equipment based on an alignment offset of constructed devices present on the substrate. The apparatus comprises an imaging setup to capture images of a plurality of constructed devices on the substrate. The imaging setup includes a processing circuitry which analyzes the captured images to detect the orientation of the constructed devices and determine an angular offset correction, based on which the substrate is aligned such that the orientation of the constructed devices is properly aligned with the optical axes of the processing equipment.

According to an aspect of the present disclosure, an apparatus for performing device alignment on a substrate is disclosed. The apparatus comprises at least one camera mounted opposite to the substrate to capture at least one image of at least a portion of a plurality of constructed devices on the substrate. The apparatus further includes a device aligner to align the substrate based on the at least portion of the constructed devices. The device aligner is configured to detect a pattern of the at least portion of the plurality of constructed devices from the at least one image to generate an alignment offset correction based on the detected pattern, and align the substrate based on the alignment offset correction.

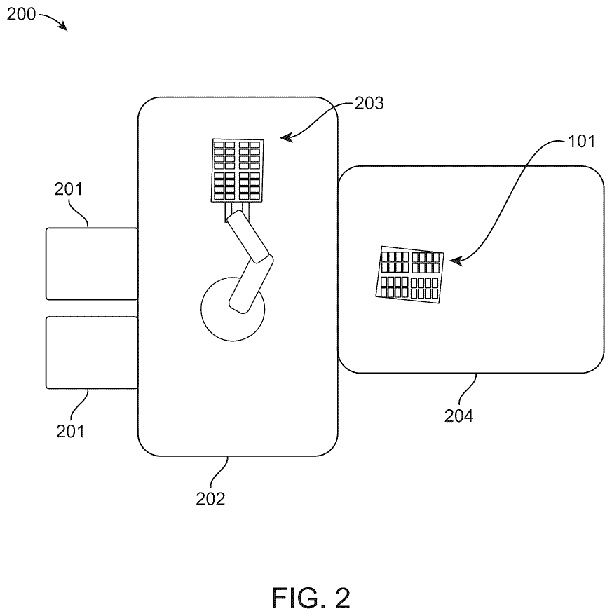

FIG. 2 illustrates a schematic diagram of a substrate handling and alignment system 200. The system 200 includes substrate carriers 201, an equipment front end module (EEFM) 202, a device aligner 203, and processing equipment 204.

The carriers 201 may be configured to store the substrate 101. In some embodiments, the substrate 101 may be a panel or a wafer as described above.

The carriers 201 may be any type of substrate carriers, such as a wafer cassette or front-opening unified pod (FOUP), to store various types of substrates, prior and post processing and metrology operations. A FOUP is a container used to portably store the substrates between various processing steps. FOUPs are typically configured to be placed at an interface of a processing tool and are generally provided with a door configured to be automatically function. A cassette is another type of carrier which can be used in place of FOUPs. Cassettes comprises an open or partially-enclosed structure with multiple slots to securely receive and store substrates in a desired orientation.

The substrate 101 stored in one of the carriers 201 is transferable to the EEFM 202. The EEFM 202 functions as an interface between the carriers 201 and other components, such as the processing equipment 204. For example, the EEFM 202 unloads the substrate 101 from the carriers 201, transfer them to the processing equipment 204, and return the substrate 101 to its carrier 201 upon completion of the processing at the processing equipment 204. To avoid contamination, the EEFM 202 is generally operated within a controlled environment. The EEFM 202 includes at least one substrate handling mechanisms configured to transfer substrates between the load ports, pre-aligners, inspection stations, and processing stages. The substrate handling mechanisms comprises wafer gripping mechanisms, robots, and robotic controller system hardware and software to facilitate the transport of wafers from one location to another.

In some embodiments, the EEFM 202 may include a pre-aligner (not shown), which is configured to perform initial positioning and alignment of the substrate 101 based on one or more alignment markings.

The pre-aligner is a subsystem of a lithography equipment configured to perform substrate centering and substrate orientation. Substrate centering is performed to adjust the position of a substrate relative to that of a substrate stage such that the center of substrate aligns with a predetermined position of the stage. Substrate orientation is performed to determine the angular orientation of the substrate relative to known reference features, such as a notch, or a fiducial mark, and align the wafer so that it is oriented at a given angle with respect to the lithography equipment axes.

The pre-aligner includes at least one imaging device to identify the alignment markings (e.g., fiducials), which are typically located on an edge of the substrate 101. The pre-aligner then positions and rotates the substrate 101 to coarsely align relative to the processing equipment 204. The coarse alignment performed by the pre-aligner is not based on the plurality of constructed devices 102 formed on the surface of the substrate 101. The pre-aligner may aid in determining an initial positional reference that ensures the substrate 101 is properly aligned to efficiently perform a fine alignment based on the orientation of the plurality of constructed devices 102 with higher accuracy.

The EEFM 202 may transfer the substrate 101 to a device aligner 203 to perform fine (or device) alignment based on the orientation of the constructed devices 102. In some embodiments, the device alignment may be performed after the pre-alignment as described above. In some embodiments, the device alignment may be performed without any alignment being performed. The device alignment is performed independent of alignment markings on substrate which is used in alignment. In some embodiments, the device aligner 203 operates as a standalone device. In some embodiments, the device aligner 203 is embedded into the processing equipment 204, as described in further detail below. In further embodiments, the device aligner 203 is integrated as part of the EEFM 202.

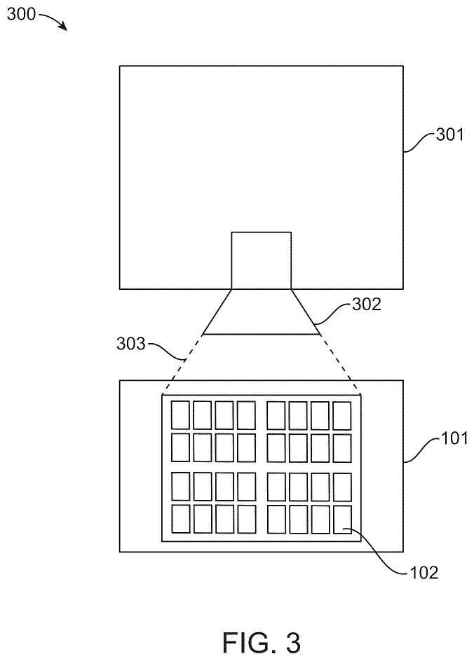

FIG. 3 illustrates a block diagram of a device aligner 300 (shown as 203 in FIG. 2). The device aligner 300 is configured to perform alignment of the substrate 101 based on the plurality of constructed devices 102 formed on the substrate 101. The constructed devices 102 comprise manufactured packages, chips, RDLS, vias, or other similar structures. The device aligner 300 includes at least one camera 302 mounted opposite to the substrate 101 to capture at least one image of at least a portion of a plurality of constructed devices 102 on the substrate 102 within its field of view (FOV) 303.

The device aligner 300 may include or is associated with one or more processors, as described in further detail below. The device aligner 300 is configured to align the substrate 101 based on the at least portion of the constructed devices 102. The device aligner 300 is configured to detect a pattern of the plurality of constructed devices 102 from the image captured by the camera 302. The device aligner 301 is further configured to generate an alignment offset correction based on the detected pattern, and align the substrate 101 based on the alignment offset correction such that the plurality of constructed devices 102 is accurately aligned to the optical axes of the processing equipment 204 (referring to FIG. 2).

The camera 302 may include one or more lenses (e.g., there may be a single variable focal-length lens or a plurality of single focal-length lenses) and an image sensor (e.g., a CCD array, a CMOS-based sensor, an active-pixel sensor, or other sensor types). The camera 302 may also include camera boards having related circuitry to facilitate image extraction. In some embodiments, the camera 302 is a color camera, which allows to capture colors to help differentiate patterns of the plurality of constructed device 102. For example, the camera 302 may have a resolution of 25 megapixel or higher.

In some embodiments, the camera 302 is mounted approximately perpendicular to an uppermost face of the substrate 101. In some embodiments, lighting is used to illuminate the substrate 101 to identify the constructed devices 102. The lighting may be of a specific type, such as yellow or filtered light, to improve contrast and visibility of the patterns of the constructed devices 102. The lighting may be used to generate a difference image to be utilized in the alignment process to facilitate precise pattern detection and alignment.

In some embodiments, the device aligner 300 may include a plurality of cameras. Each camera may have a respective FOV corresponding to different portions of the substrate 101. In some embodiments, the substrate 101 may include a plurality of groups of constructed devices and the plurality of cameras may be positioned to observe a respective group of the constructed devices.

As mentioned above, the device aligner 300 is configured to detect a pattern of the plurality of constructed devices 102 from the images captured by the camera 302 and generate an alignment offset correction based on the detected pattern. For example, the device aligner 300 detects a pattern of the at least portion of the plurality of constructed devices 102 from the captured images using various pattern recognition algorithms.

In some embodiments, the device aligner 300 is further configured to perform cross-correlation of the detected pattern and a template image and to detect an offset error based on the cross-correlation. The offset error is determined using cross-correlation between pixel values of the captured images and a corresponding template image at respective displacements; and normalizing the cross-correlation by a standard deviation of the pixel values.

The detected patterns of the constructed devices 102 in the captured image is matched with patterns in the template image. The template is an image of a model substrate with accurately aligned pattern of constructed devices. In some examples, normalized cross correlation (NCC) technique is utilized to measure the cross-correlation between pixel values in the captured image and the template image at respective displacements while normalizing the correlation by a standard deviation of the two inputs. That is, the template is slid over the captured image, and the normalized cross-correlation at each position can be calculated. The calculations identify positions with high correlation scores which indicate matching alignment between the detected pattern of the constructed devices in the captured image and the pattern in the template image. The device aligner 300 generates an alignment offset error based on the displacement associated with the lowest correlation score and the substrate 101 is aligned accordingly, thereby aligning the constructed devices 102 with the optical axes of the processing equipment 204.

In some embodiments, the device aligner 300 uses a machine learning model to generate the alignment offset correction. In some embodiments, a machine-learning model, such as a convolutional neural-network (CNN or convnet), is used to process image data to detect patterns of the constructed devices 102 of the substrate 101. Processing image data includes, for example, finding spatial relationships within captured images to detect patterns of the constructed devices 102. Using the captured images as an input to the machine-learning model, the machine-learning model produces at least one output that indicates, for example, a detected location or orientation of the device pattern, a computed alignment offset of the substrate, and/or a degree of positional deviation such as translation or rotation (e.g., in x-, y-, z-, or θ-directions) relative to optical axis of the processing equipment 204.

In some embodiments, the image(s) of the substrate 101 captured by the at least one camera 302 is processed in the machine-learning model to detect patterns of the constructed device 102 of the substrate 101. The machine-learning model compares the detected patterns overlaying these captured images (e.g., virtually overlayed in the machine-learning model or a processor comparing the processed images) on each other to determine the alignment offset of the constructed devices 102 across the substrate 102. The comparison of captured images of the substrate 101 allows for the detected pattern of the constructed devices 102 to be more accurately delineated with reference to an actual location of the detected pattern with reference to the remainder of the substrate and/or edges of the substrate 101.

The machine-learning model may include a pre-processor and a machine-learning network. The captured image of the substrate 101 is provided to the pre-processor where the pre-processor filters or otherwise processes the image to, for example, crop, scale, or otherwise change or enhance the image and to generate a pre-processed image.

The pre-processed image is then given as input into the machine-learning network. The machine-learning network is provided as a multi-layered machine learning model. The machine-learning network includes four layers including an input layer, a feature-extraction layer, a features-relationship layer, and a decision layer. The decision layer may have a number of outputs including pattern detection of the constructed devices 102 of the substrate 101.

The pixel information from the pre-processed image is sent to the input layer. Each node in the input layer may correspond to a pixel of the pre-processed image. The machine-learning network, in an iterative manner, may be trained in one or more of the layers. The decision layer provides output decisions regarding the various substrate characteristics of a given substrate 101, as noted above. The characteristics of the substrate 101 are then generated in output box. The output box therefore stores the extracted substrate characteristics from the raw image. In various embodiments, the output box provides a textual indication showing the characteristics of the constructed devices 102 (e.g., offsets in a theta-direction, and other characteristics of the substrate). In various embodiments, values and/or characteristics within the output box may be input as a command to, for example, direct the rotating mechanism to reposition the substrate in expected x, y, z, and/or angular position)

In some embodiments, pixels within the captured images can be converted to physical units (e.g., a linear dimension, such as millimeters) via an algorithm such as a direct linear transformation (DLT) transformation matrix. The DLT transformation matrix is predetermined and embedded into the machine-learning model or other processing environment. Either a two-dimensional (2D) or a three-dimensional (3D) transformation matrix can be calculated to determine an angular offset and generate the alignment offset correction value based on which the substrate 101 is adjusted to precisely align with the optical axes of the processing equipment 204. In some embodiments, captured images are transferred to the machine-learning model to calculate at least a center offset (e.g., in at least an x-direction and a y-direction) and a rotational correction, if needed.

The machine learning model is first used in a training mode, to train the machine-learning model, and then later be used in a normal-operation mode to detect a pattern of the plurality of constructed devices 102 from the captured images and generate an alignment offset correction based on the detected pattern. In various embodiments, the training mode may be performed by a manufacturer of the substrate-characterization system. Data obtained from the training mode may then be used at, for example, a fabrication facility (e.g., a semiconductor-device manufacturer or “fab”) to determine characteristics of each substrate used within the facility. Thus, the disclosed apparatus for performing device alignment on the substrate leveraging the machine learning model allows an adaptive approach for substrate alignment by maintaining reliable pattern detection and offset correction throughout the fabrication process.

The device aligner 300 is further configured to effectuate the alignment of the substrate 101 based on the alignment offset correction. For example, the substrate handling and alignment system 200, described above with reference to FIG. 2, may include communication circuitry which communicatively and operatively couples the device aligner 300 to the carrier 201, EEFM 202, and processing equipment 204. In some embodiments, the device aligner 300 instructs a rotation mechanism to rotate and/or translate the substrate 101 based on the alignment offset correction and provide the substrate 101 for the further processing to the processing equipment 204. In some embodiments, the processing equipment 204 is a lithography equipment. In some embodiments, the processing equipment 204 is an inspection or a metrology equipment.

In some embodiments, the rotation mechanism is a robotic arm functioning as part of the EEFM 202 configured to grasp and move the substrate 101. The device aligner 300 (also referred to as device aligner 203) is operatively coupled to the robotic arm and instructs the robotic arm to rotate and/or translate the substrate 101 based on the generated alignment offset correction to accurately align the constructed devices 102 relative to the optical axes of the processing equipment 204. In some embodiments, the robotic arm transfers the substrate 102 to an inspection, metrology, or lithography stage for subsequent processing.

In some embodiments, the rotation mechanism is integrated with the processing equipment 204. For example, the processing equipment 204 may include a stage chuck on which the substrate 101 is mounted. The stage chuck is rotatable about a defined axis and is operatively coupled to the device aligner 300. The device aligner 300 transmits a control signal to the stage chuck to rotate and/or translate the substrate 101 based on the generated alignment offset correction, thereby aligning the detected pattern of the constructed device pattern 102 relative to the optical axes of the processing equipment 204.

In further embodiments, the device alignment is performed in multiple stages by means of a rotatable chuck of the processing equipment 204. For example, the apparatus for device alignment comprising the device aligner 301 detects a pattern on a first set of constructed devices 102 on the substrate 101 and a first alignment offset correction is generated for the first set of constructed devices 102. The device aligner 301 then rotates and/or translates the substrate 101 based on the first alignment offset correction followed by transfer to the processing equipment 204. Subsequently, the device aligner 301 detects a pattern on a second set of constructed devices 102 on the substrate 101 and a second alignment offset correction is generated for the second set of constructed devices 102. The device aligner 301 then rotates and/or translates the substrate 101 based on the second alignment offset correction followed by transfer to the processing equipment 204. This approach of alignment offset correction in multiple stages allows high-precision inspection of multiple sets of patterns of the constructed devices on a single substrate, thereby improving process flexibility and throughput.

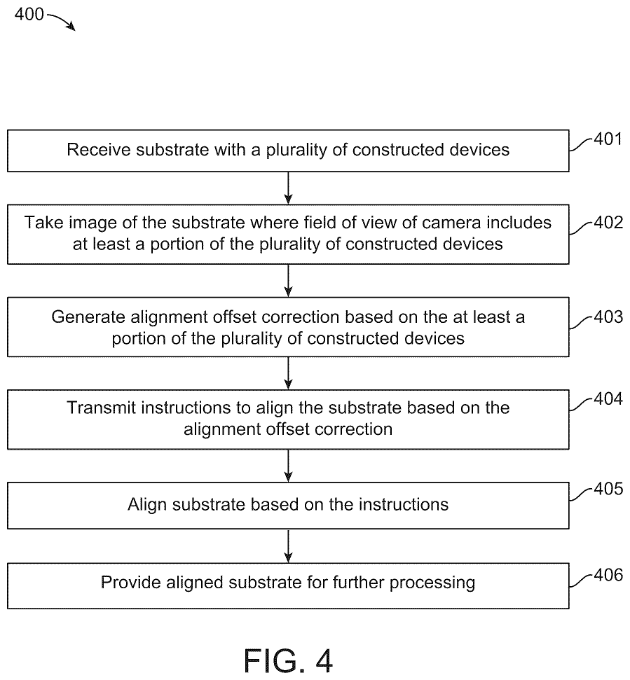

FIG. 4 shows a flow diagram of a method 400 for device alignment on a substrate. In some embodiments, method 400 may be performed by the device aligner 300 for performing device alignment on a substrate 101 as described above.

At operation 401, a substrate (e.g., the substrate 101) is received. The substrate includes a plurality of constructed devices (e.g., the constructed devices 102). For example, a substrate handling mechanism of an EEFM may provide the substrate at a device aligner. At operation 402, one or more images of the substrate are captured where a field of view of camera includes at least a portion of the plurality of constructed devices. For example, one or more cameras may capture images of the substrate.

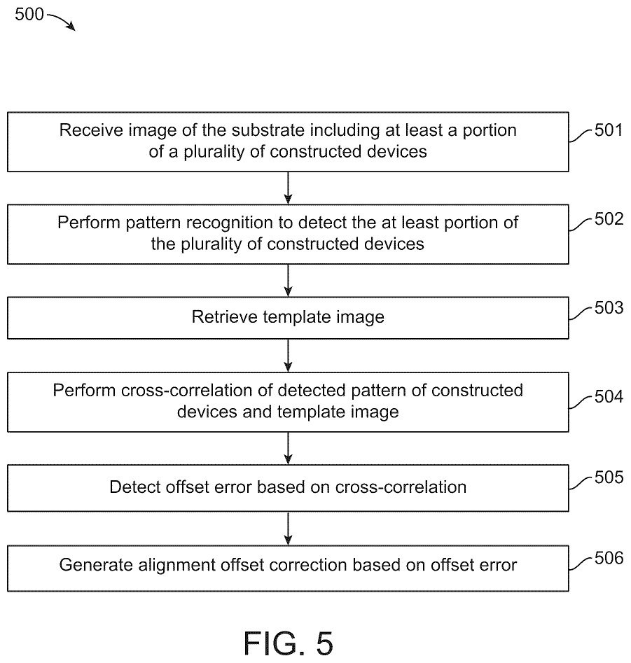

At operation 403, the captured images are processed to generate an alignment offset correction based on the at least a portion of the plurality of constructed devices. For example, cross-correlation (as described in further detail below with reference to FIG. 5) or a machine-learning framework may be used to generate the alignment offset correction. If a misalignment of the constructed devices is detected from the processed images, instructions to align (e.g., rotate and/or translate) the substrate based on the alignment offset correction (e.g., x-offsets, y-offsets, and/or angle-offsets) is transmitted to a rotating mechanism at operation 404.

At operation 405, the rotating mechanism aligns (e.g., rotates and/or translates) the substrate based on the alignment offset correction. In some embodiments, the rotation mechanism is a robotic arm functioning as part of the EEFM 202 described above configured to grasp and move the substrate. Based on the generated alignment offset correction the robotic arm rotates and/or translates the substrate to accurately align the constructed devices relative to the optical axes of the processing equipment 204, for example. In another embodiment, the rotation mechanism includes a stage chuck on which the substrate is mounted. The stage chuck rotates and/or translates the substrate based on transmitted the generated alignment offset correction, thereby aligning the detected pattern of the constructed device pattern relative to the optical axes of the processing equipment.

At operation 405, the aligned substrate is provided for further processing to the processing equipment. In some embodiments, the further processing comprises inspection of the substrate 101. In some embodiments, the further processing comprises a lithography process.

FIG. 5 shows a flow diagram of a method 500 for generating alignment offset correction using cross-correlation. At operation 501, one or more images of the substrate including at least a portion of a plurality of constructed devices is received. At operation 502, pattern recognition is performed to detect patterns of the plurality of constructed devices using pattern recognition algorithms.

At operation 503, a template image is retrieved, which is an image of a model substrate with accurately aligned pattern of constructed devices. At operation 504, a cross-correlation of detected pattern of constructed devices and template image is performed. In some embodiments, a normalized cross correlation (NCC) technique is used to detect and correct the alignment offset error. The NCC uses the retrieved template image of the substrate to match each pattern detected constructed devices in the captured image to the ones in the template image. The normalized cross correlation technique measures the cross-correlation between pixel values in the captured image and the template image at respective displacements while normalizing the correlation by a standard deviation of the two inputs. That is, the template image can be slid over the captured image, and the normalized cross-correlation at each position can be calculated. The calculations can identify positions with high correlation indicate matching alignment between the detected pattern of the constructed devices in the captured image and the pattern in the template image.

The following information is extracted after performing cross-correlation: a location of the constructed devices; orientation of the constructed devices; an amount the constructed devices is misaligned relative to outside boundary of the substrate (e.g., a misalignment in an x-direction, a y-direction, a z-direction, and/or a theta-direction), and an amount the constructed devices 102 is misaligned relative to optical axes of the processing equipment (e.g., the processing equipment 204). Based on the aforesaid information, an offset error is detected at operation 505.

At operation 506, an alignment offset correction (e.g., x-offsets, y-offsets, and/or angle-offsets) is generated based on the detected offset error. The alignment offset correction is then applied to rotate and/or translate the substrate by a rotating mechanism, for example, the robotic arm or rotating stage chuck. The repositioning of the substrate based the alignment offset correction is then applied to rotate and/or translate the substrate allows the aligning of the constructed devices with the optical axes of the processing equipment.

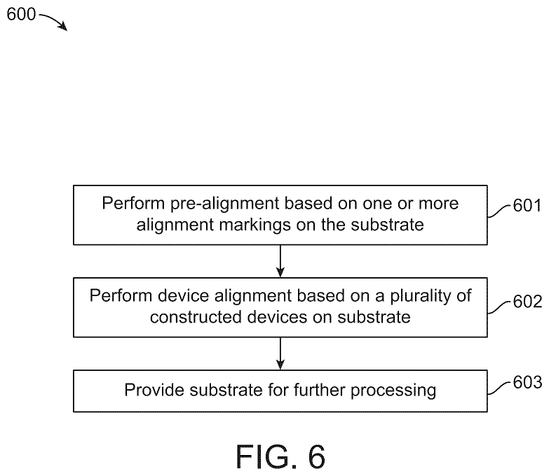

As mentioned above, pre-alignment and device alignment may be used in conjunction. FIG. 6 shows a flow diagram of a method 600 for performing pre-alignment and device alignment. At operation 601, a pre-alignment system performs pre-alignment of the substrate based on one or more alignment markings on the substrate. The alignment markings include as a notch, a flat portion on an edge of the substrate or any fiducial mark etched on an edge of the substrate. During pre-alignment, only the alignment markings may be used to perform a coarse alignment of the substrate.

At operation 602, a device alignment system further performs device alignment based on a plurality of constructed devices on substrate as described herein. At operation 603, the substrate is provided for further processing. In some embodiments, the further processing comprises inspection of the substrate or any lithographic process.

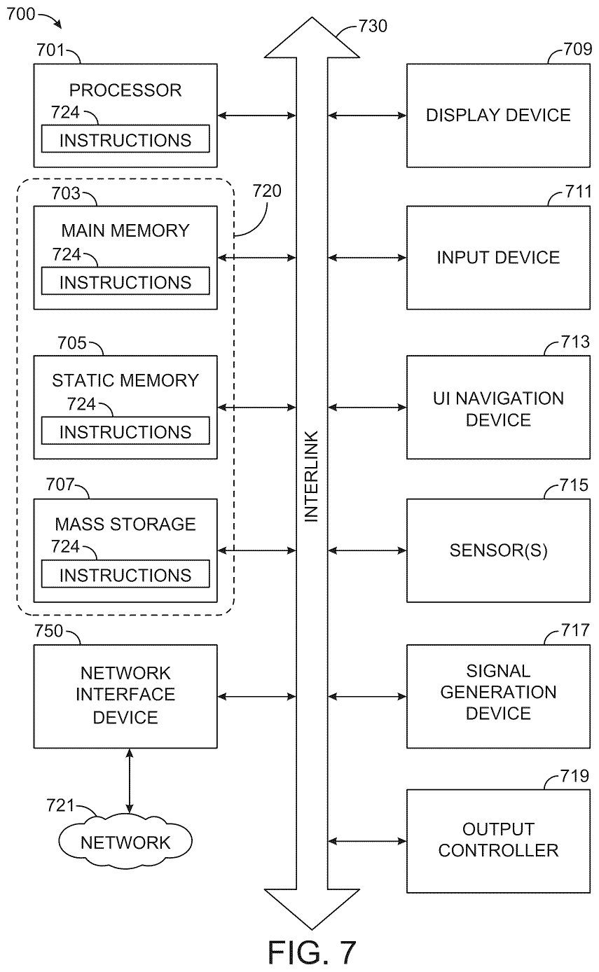

The techniques shown and described in this document can be performed using a portion or an entirety of apparatus/system to perform device alignment on a substrate as shown in the figures described above, in combination with, or otherwise using a machine 700 as discussed below in relation to FIG. 7. FIG. 7 illustrates a block diagram of an example comprising a machine 700 upon which any one or more of the techniques (e.g., methodologies) discussed herein may be performed. In various examples, the machine 700 may operate as a standalone device or may be connected (e.g., networked) to other machines.

In a networked deployment, the machine 700 may operate in the capacity of a server machine, a client machine, or both in server-client network environments. In an example, the machine 700 may act as a peer machine in peer-to-peer (P2P) (or other distributed) network environment. The machine 700 may be a personal computer (PC), a tablet device, a set-top box (STB), a personal digital assistant (PDA), a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate by, logic or a number of components, or mechanisms. Circuitry is a collection of circuits implemented in tangible entities that include hardware (e.g., simple circuits, gates, logic, etc.). Circuitry membership may be flexible over time and underlying hardware variability. Circuitries include members that may, alone or in combination, perform specified operations when operating. In an example, hardware of the circuitry may be immutably designed to carry out a specific operation (e.g., hardwired). In an example, the hardware comprising the circuitry may include variably connected physical components (e.g., execution units, transistors, simple circuits, etc.) including a computer-readable medium physically modified (e.g., magnetically, electrically, such as via a change in physical state or transformation of another physical characteristic, etc.) to encode instructions of the specific operation. In connecting the physical components, the underlying electrical properties of a hardware constituent may be changed, for example, from an insulating characteristic to a conductive characteristic or vice versa. The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine 700 (e.g., computer system) may include a hardware-based processor 701 (e.g., a central processing unit (CPU), a graphics processing unit (GPU), a hardware processor core, or any combination thereof), a main memory 703 and a static memory 705, some or all of which may communicate with each other via an interlink 730 (e.g., a bus). The machine 700 may further include a display device 709, an input device 711 (e.g., an alphanumeric keyboard), and a user interface (UI) navigation device 713 (e.g., a mouse). In an example, the display device 709, the input device 711, and the UI navigation device 713 may comprise at least portions of a touch screen display. The machine 700 may additionally include a storage device 720 (e.g., a drive unit), a signal generation device 717 (e.g., a speaker), a network interface device 750, and one or more sensors 715, such as a global positioning system (GPS) sensor, compass, accelerometer, or other sensor. The machine 700 may include an output controller 719, such as a serial controller or interface (e.g., a universal serial bus (USB)), a parallel controller or interface, or other wired or wireless (e.g., infrared (IR) controllers or interfaces, near field communication (NFC), etc., coupled to communicate or control one or more peripheral devices (e.g., a printer, a card reader, etc.).

The storage device 720 may include a machine readable medium on which is stored one or more sets of data structures or instructions 724 (e.g., software or firmware) embodying or utilized by any one or more of the techniques or functions described herein. The instructions 724 may also reside, completely or at least partially, within a main memory 703, within a static memory 705, within a mass storage device 707, or within the hardware-based processor 701 during execution thereof by the machine 700. In an example, one or any combination of the hardware-based processor 701, the main memory 703, the static memory 705, or the storage device 720 may constitute machine readable media.

While the machine readable medium is considered as a single medium, the term “machine readable medium” may include a single medium or multiple media (e.g., a centralized or distributed database, and/or associated caches and servers) configured to store the one or more instructions 724.

The term “machine readable medium” may include any medium that is capable of storing, encoding, or carrying instructions for execution by the machine 700 and that cause the machine 700 to perform any one or more of the techniques of the present disclosure, or that is capable of storing, encoding or carrying data structures used by or associated with such instructions. Non-limiting machine-readable medium examples may include solid-state memories, and optical and magnetic media. Accordingly, machine-readable media are not transitory propagating signals. Specific examples of massed machine readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic or other phase-change or state-change memory circuits; magnetic disks, such as internal hard disks and removable disks; magneto-optical disks; and CD-ROM and DVD-ROM disks.

The instructions 724 may further be transmitted or received over a communications network 721 using a transmission medium via the network interface device 750 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., the Institute of Electrical and Electronics Engineers (IEEE) 802.22 family of standards known as Wi-Fi®, the IEEE 802.26 family of standards known as WiMax®), the IEEE 802.27.4 family of standards, peer-to-peer (P2P) networks, among others. In an example, the network interface device 750 may include one or more physical jacks (e.g., Ethernet, coaxial, or phone jacks) or one or more antennas to connect to the communications network 721. In an example, the network interface device 750 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by the machine 700, and includes digital or analog communications signals or other intangible medium to facilitate communication of such software.

### Various Notes

Each of the non-limiting aspects above can stand on its own or can be combined in various permutations or combinations with one or more of the other aspects or other subject matter described in this document.

The above detailed description includes references to the accompanying drawings, which form a part of the detailed description. The drawings show, by way of illustration, specific implementations in which the invention can be practiced. These implementations are also referred to generally as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following aspects, the terms “including” and “comprising” are open-ended, that is, a system, device, article, composition, formulation, or process that includes elements in addition to those listed after such a term in an aspect are still deemed to fall within the scope of that aspect. Moreover, in the following aspects, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other implementations can be used, such as by one of ordinary skill in the art upon reviewing the above description. The Abstract is provided to allow the reader to quickly ascertain the nature of the technical disclosure. It is submitted with the understanding that it will not be used to interpret or limit the scope or meaning of the aspects. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed implementation. Thus, the following aspects are hereby incorporated into the Detailed Description as examples or implementations, with each aspect standing on its own as a separate implementation, and it is contemplated that such implementations can be combined with each other in various combinations or permutations.

What is claimed is:

1. An apparatus for performing device alignment on a substrate, comprising:
at least one camera mounted opposite the substrate to capture at least one image of at least a portion of a plurality of constructed devices on the substrate;
a device aligner to align substrate based on the at least portion of the constructed devices, wherein the device aligner is configured to detect a pattern of the at least portion of the plurality of constructed devices from the at least one image, generate an alignment offset correction based on the detected pattern, and aligns the substrate based on the alignment offset correction.

2. The apparatus of claim 1, wherein the device aligner is further configured to provide the aligned substrate to a machine for further processing.

3. The apparatus of claim 2, wherein the further processing comprises inspection of the substrate.

4. The apparatus of claim 2, wherein the further processing comprises a lithography process.

5. The apparatus of claim 1, wherein the device aligner is further configured to perform cross-correlation of the detected pattern and a template image and to detect an offset error based on the cross-correlation.

6. The apparatus of claim 1, wherein the device aligner is configured to rotate the substrate based on the alignment offset correction.

7. The apparatus of claim 1, wherein the device aligner is configured to translate the substrate a x and/or y direction based on the alignment offset correct.

8. The apparatus of claim 1, wherein the device aligner is configured to rotate the substrate to align the plurality of constructed devices on the substrate to optical axes of a receiving equipment.

9. The apparatus of claim 1, wherein the plurality of constructed devices comprise manufactured packages, chips, RDLS, or vias.

10. The apparatus of claim 1, wherein the device alignment is performed independent of alignment markings on substrate.

11. The apparatus of claim 1, further comprising:
a pre-aligner to align the substrate based on one or more alignment markings on the substrate.

12. A method for device alignment on a substrate, the method comprising:
receiving a substrate comprising a plurality of constructed devices;
capturing at least one image of the substrate, the image comprising at least a portion of the plurality of constructed devices;
detecting a pattern of the at least portion of the plurality of constructed devices based on the at least one image;
generating an alignment offset correction based on the detected pattern; and
aligning the substrate based on the alignment offset correction.

13. The method of claim 12, further comprising:
providing the aligned substrate to a machine for further processing.

14. The method of claim 13, wherein the further processing comprises inspection of the substrate.

15. The method of claim 13, wherein the further processing comprises a lithography process.

16. The method of claim 12, further comprising:
performing cross-correlation of the detected pattern and a template image; and
detecting an offset error based on the cross-correlation.

17. The method of claim 12, wherein aligning comprises rotating or translating the substrate.

18. The method of claim 12, wherein the plurality of constructed devices comprise manufactured packages, chips, RDLS, or vias.

19. The method of claim 12, wherein the device alignment is performed independent of alignment markings on substrate.

20. A pre-alignment system comprising:
at least one camera mounted opposite a substrate to capture at least one image of at least a portion of a plurality of constructed devices on the substrate; and
means for aligning the substrate based on the at least portion of the plurality of constructed devices on the substrate.
